(19) United States
(12) Patent Application Publication
(10) Pub. No.: US 2015/0364298 A1
(43) Pub. Date: Dec. 17, 2015

(54) LITHOGRAPHY APPARATUS, AND METHOD OF MANUFACTURING ARTICLE

(71) Applicant: CANON KABUSHIKI KAISHA, Tokyo (JP)

(72) Inventors: Masashi Kotoku, Yokohama-shi (JP); Kuniyasu Haginiwa, Yokohama-shi (JP)

(21) Appl. No.: 14/736,388

(22) Filed: Jun. 11, 2015

(30) Foreign Application Priority Data
Jun. 16, 2014 (JP) 2014-123810

(51) Int. Cl. H01J 37/302; H01J 37/317

(52) U.S. Cl. CPC H01J 37/3023; H01J 37/3174

(57) ABSTRACT

There is provided a lithography apparatus advantageous in a process on a substrate, on which patterning has been performed thereby, that an external apparatus performs (in a succeeding step). The apparatus includes a controller and a transmitter. The controller extracts log information to be transmitted to the external apparatus that performs a process on the substrate, on which the patterning has been performed, among log information associated with the patterning. The transmitter transmits the extracted log information to the external apparatus.

### BACKGROUND OF THE INVENTION

1. Field of the Invention

The present invention relates to a lithography technique for performing patterning on a substrate with a charged particle beam.

2. Description of the Related Art

A semiconductor device is manufactured by repeatedly performing, for example, a deposition step and a patterning step including a lithography step and etching step for a semiconductor substrate (to be referred to as a “wafer” hereinafter). As for a wafer processed in each step such as a deposition step or patterning step, a specific number (for example, 25) of wafers is managed as one lot in a general semiconductor device mass production plant. In each step, it is inspected whether a semiconductor device as a finished product satisfies a standard defined so as to operate as designed.

Japanese Patent No. 3938409 relates to a substrate processing apparatus for transferring substrate information between a plurality of processing units, and describes that the substrate information includes a lot number, a number indicating the loading order of substrates, and a recipe number indicating a substrate conveyance procedure.

To perform high-precision connection and overlay drawing, the current, position, and shape of a charged particle beam, and driving of a stage need to be stable. However, in a lithography step using a charged particle beam, patterning is performed while scanning a wafer with a beam. When, therefore, performing patterning on a region corresponding to a shot of an exposure apparatus, it takes time from when the first pattern is formed until the last pattern is formed. During this time, it is difficult to stabilize a beam from the start to end of drawing on a wafer without performing correction in the middle of drawing, and to make driving of the stage fall within a given error. This is contrary to an exposure apparatus for forming a circuit pattern using a mask, which performs patterning in a shot at once under the same condition.

Furthermore, in a multi-beam charged particle beam drawing apparatus capable of performing drawing in a wide angle of view using a number of charged particle beams, many charged particle beams are to be adjusted, and it is thus more difficult to stabilize all the charged particles. Therefore, a global alignment method of performing alignment only once before performing drawing on a wafer, which is generally used by an exposure apparatus that uses a mask, is insufficient for the charged particle beam drawing apparatus. Consequently, it is necessary to use a dye-by-dye alignment method of repeatedly performing an alignment step many times while performing patterning on one wafer, or a drawing sequence complying with the method.

Accordingly, to improve the overlay precision when forming a layer later, and correctly distinguish a defective item in an inspection step, it is particularly necessary to notify an external apparatus of a condition when drawing an alignment mark or inspection mark. The same problem arises in a cluster charged particle beam drawing apparatus forming a large apparatus by combining a plurality of units each serving as a component and having a charged particle beam drawing function.

As described above, it is difficult to stabilize drawing with a charged particle beam in a given state, and the apparatus state and drawing condition vary for each unit. Therefore, it is necessary to recognize, in succeeding processing, a specific unit and a specific condition which have been used to process each wafer. However, the external apparatus has no way to know about the characteristics of a unit and a condition which have been used to perform drawing on a wafer unloaded from the charged particle beam drawing apparatus.

If a specific unit which has processed a wafer cannot be specified when a defect is found by inspecting the wafer, all the remaining units in the cluster need to be stopped and inspected, thereby significantly decreasing the productivity.

### SUMMARY OF THE INVENTION

The present invention provides, for example, a lithography apparatus advantageous in a process on a substrate, on which patterning has been performed thereby, that an external apparatus performs (in a step subsequent to the patterning).

According to one aspect of the present invention, a lithography apparatus for performing patterning on a substrate with a charged particle beam is provided. The apparatus includes a controller configured to extract log information to be transmitted to an external apparatus that performs a process on the substrate, on which the patterning has been performed, among log information associated with the patterning, and a transmitter configured to transmit the extracted log information to the external apparatus.

Further features of the present invention will become apparent from the following description of exemplary embodiments (with reference to the attached drawings).

### BRIEF DESCRIPTION OF THE DRAWINGS

FIG. 1 is a block diagram showing the arrangement of a charged particle beam drawing apparatus according to an embodiment;

FIG. 2 is a view showing an example of drawing log information according to the embodiment;

FIG. 3 is a flowchart illustrating drawing processing according to the embodiment;

FIG. 4 is a view showing the scan regions of a wafer;

FIG. 5 is a block diagram showing the arrangement of a cluster charged particle beam drawing apparatus according to the second embodiment;

FIG. 6 is a flowchart illustrating drawing processing according to the second embodiment; and

FIG. 7 is a view showing an example of drawing log information according to the second embodiment.

### DESCRIPTION OF THE EMBODIMENTS

Various exemplary embodiments, features, and aspects of the invention will be described in detail below with reference to the drawings.

Embodiments of the present invention will be described in detail below with reference to the accompanying drawings. Note that the present invention is not limited to the following embodiments, and these embodiments are merely practical examples advantageous when carrying out the present invention. Also, not all combinations of features explained in the following embodiments are essential for the present invention to solve the problem.

### First Embodiment

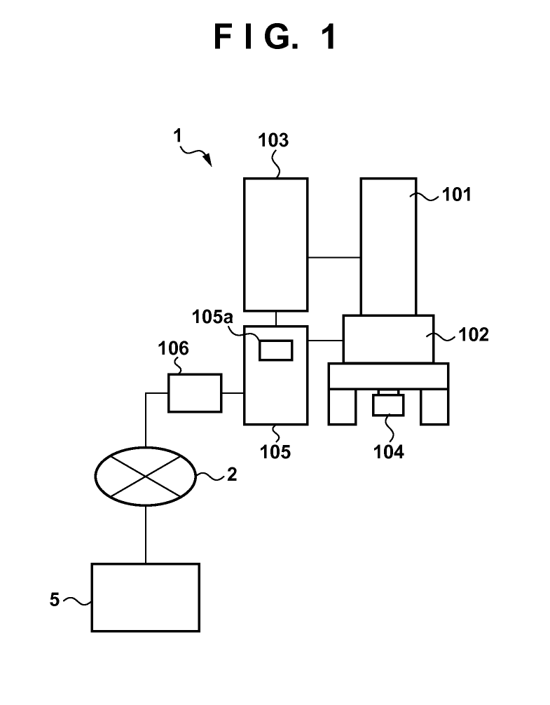

The arrangement of a charged particle beam drawing apparatus according to the embodiment will be described below with reference to FIG. 1. A charged particle beam drawing apparatus 1 performs patterning on a substrate with a charged particle beam. The charged particle beam drawing apparatus 1 includes an electron optical system controller (control system) 101, a stage controller 102, a pattern data controller 103, a vacuum controller 104, a log processor (processing system) 105, and a transmitter 106. The log processor 105 can form a main controller (part of it) for controlling other components.

The electron optical system controller 101 forms a charged particle optical system including an electron gun for generating electrons, a blanker for turning on/off an electron beam at high speed, and an electromagnetic lens for reducing a beam. The charged particle optical system functions as a patterning device for performing patterning. The stage controller 102 includes an XYZ stage for holding and moving a wafer as a substrate, and a laser measuring system. The pattern data controller 103 manages circuit pattern data, and sends drawing pattern data to a main body. The vacuum controller 104 controls the degrees of vacuum of a chamber and load lock chamber accommodating the charged particle optical system and stage. The log processor 105 collects (acquires), as drawing log information (log information), pieces of information acquired by various sensors and the result of processing. The log processor 105 stores the drawing log information in a storage 105a. The transmitter 106 is communicably connected, via a LAN 2, to an external apparatus 5 for managing a succeeding step. More specifically, the external apparatus 5 processes a substrate, on which patterning has been performed, among the pieces of log information about patterning.

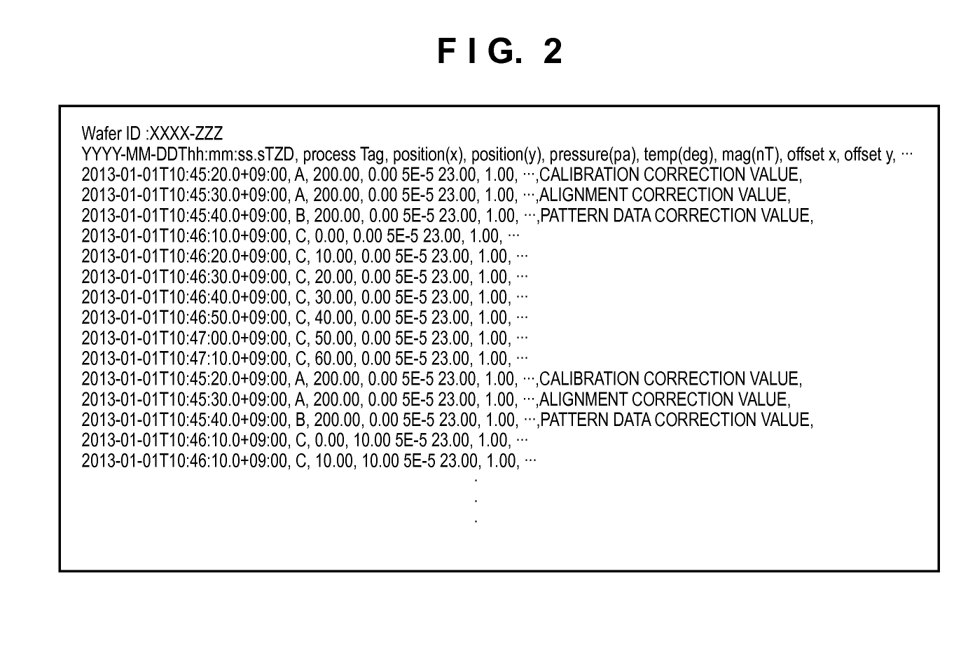

The charged particle beam drawing apparatus 1 advances processing while writing drawing log information in the log processor 105. The drawing log information includes the following data in addition to a wafer ID and time stamp. FIG. 2 shows an example of when drawing log information is recorded in a file.

As an example, the log information includes items of environment information such as the temperature, magnetic field, and degree of vacuum acquired at a given interval during a drawing period. The external apparatus uses the environment information to find an abnormality which is difficult to find since the abnormality does not satisfy an error condition specific to the drawing apparatus. If the correlation between the environment information and a wafer inspection result is recognized, the charged particle beam drawing apparatus is notified of an abnormality.

As another example, the log information includes an item of the environment information acquired at the time of drawing an inspection mark or alignment mark. Deformation of the wafer due to the temperature influences the position precision of the inspection mark or alignment mark. If heat information is obtained, it is possible to estimate the deformation amount of the wafer at the time of drawing the inspection mark or performing alignment measurement. This improves the inspection precision, and makes it possible to estimate the overlay precision in consideration of the deformation amount of the wafer.

As still another example, the log information includes an item of alignment step result information or calibration result information periodically inserted in accordance with a drawing position on the wafer. This makes it possible to check the overlay precision of each local region of the wafer. Depending on a condition, it is possible to determine whether each chip on the wafer is a non-defective item or defective item.

As still another example, the log information includes an item of information (difference data corrected based on original data) about pattern data used for patterning, which has been obtained via correction corresponding to a drawing position. The pattern data information obtained by correcting the aberrations and distortion of the electron optical system of each charged particle beam drawing apparatus is used to find the cause of an abnormality.

As still another example, the log information includes the environment information and alignment result information acquired at the time of start and end of drawing regardless of acquisition at a given interval or acquisition in accordance with a drawing position. Data at the time of start and end of processing can be represented to simplify processing in the succeeding step.

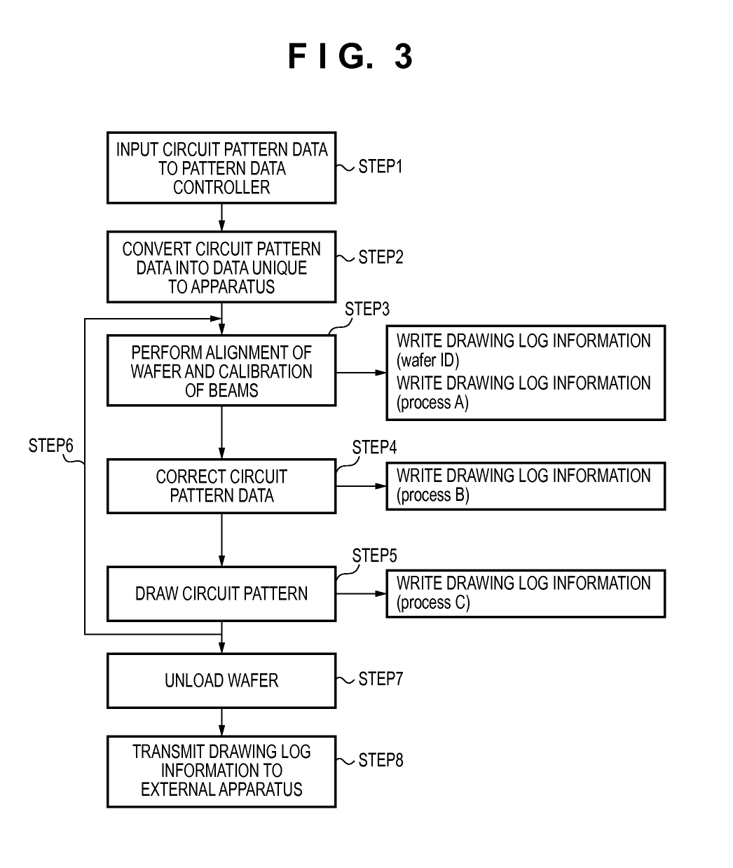

A processing procedure in the charged particle beam drawing apparatus will be described with reference to FIG. 3. A process tag for identifying a specific process which outputs a drawing log is assigned for the sake of convenience. First, circuit pattern data generated by the user by using a CAD tool is input to the computer of the pattern data controller 103 (step 1). The pattern data controller 103 converts the circuit pattern data into data unique to the apparatus (step 2). At this time, a multi-beam charged particle beam drawing apparatus may form a circuit pattern on the entire surface of a chip by performing drawing twice or more so as to restrict the number of beams and allow defects in some beams. In this case, in accordance with the beam defect state of the charged particle beam drawing apparatus, drawing data unique to the apparatus is generated.

After checking the apparatus state and making a preparation before drawing by performing various measurement operations, the controller performs calibration of the beams and alignment measurement of the wafer (step 3). At this time, the controller extracts information about at least one of calibration and measurement, and writes it in the drawing log information. Process tag A is added to the log of this process. Based on the result, correction of the electron optical system controller 101, correction of the stage controller 102, and modification of the drawing pattern data are performed (step 4). Drawing pattern data modification information is also written in the drawing log information. Process tag B is added to the log of this process. Upon start of drawing, environment information such as the degree of vacuum, magnetic field, and temperature is written in the drawing log information. After that, one wafer is scanned several ten to several thousand times to perform drawing on the entire surface of the wafer while driving the stage by the stage controller 102 (step 5). Process tag C is added to the log of this process.

If performing alignment only once upon start of drawing cannot achieve necessary precision, alignment is repeatedly performed while performing drawing on one wafer. For example, every time alignment is performed, information such as an alignment result, the degree of vacuum, the magnetic field, and the temperature of the wafer, column, or the like is written in the drawing log information.

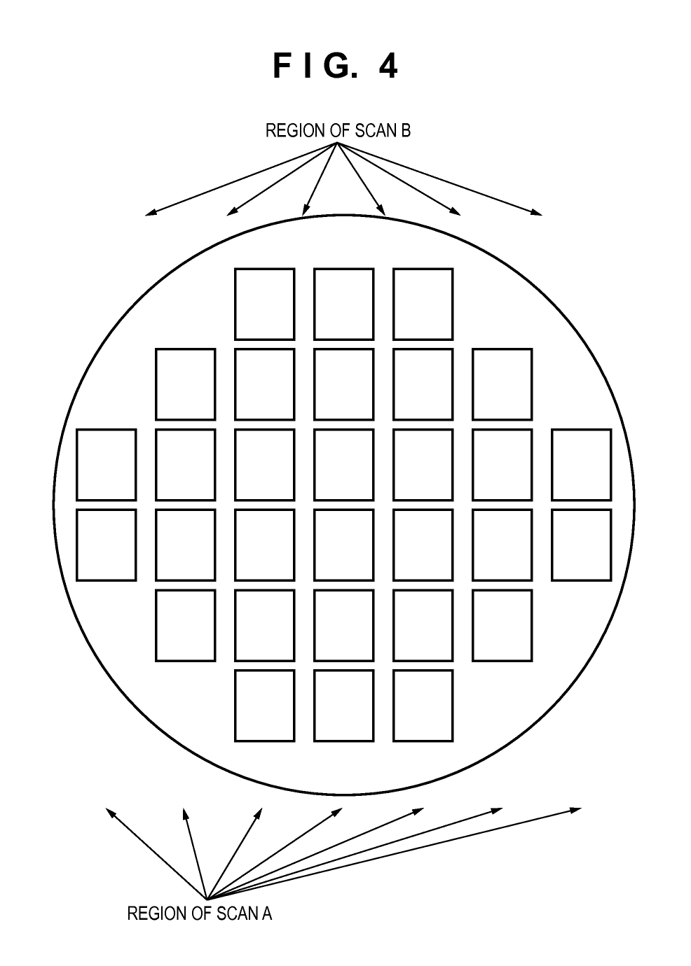

As shown in FIG. 4, when scanning the wafer to perform drawing, the wafer can be divided into a scan region (a region of scan A) which is mostly occupied by the circuit pattern, and a scan region (a region of scan B) which includes a number of alignment marks or inspection marks at the edge of the circuit pattern. Scan A processes most of the wafer but especially scan B influences the overlay precision. Thus, the controller extracts information about at least one of the degree of vacuum, magnetic field, and temperature and writes it in the drawing log information at the start (and end) of scan A and the start (and end) of scan B. While writing the drawing log information in this way, steps 3 to 5 are repeated until drawing on the entire surface of the wafer is completed (step 6). Every time patterning is performed on the wafer in the lithography step, log information about the patterning processing is stored in the storage. Upon completion of drawing, the log processor 105 writes the drawing log information at the time of completion. The charged particle beam drawing apparatus 1 controls the stage controller 102 to unload the wafer toward a developing apparatus by a conveyance robot (not shown) (step 7). After that, the transmitter 106 transmits the drawing log information extracted during the period from the start to end of drawing to the external apparatus 5 via the LAN 2 (step 8). As the external apparatus, for example, the following apparatus is assumed.

An example of the external apparatus is an inspection apparatus. For example, the inspection apparatus determines whether a drawing error falls within an allowable value range, in consideration of distortion at the time of drawing an inspection mark from the wafer temperature information included in the drawing log information.

Another example of the external apparatus is the second lithography apparatus for forming an upper layer. The second lithography apparatus corrects, for example, the position of an alignment mark based on the circuit pattern data (or correction information thereof), the alignment result, and the environment information included in the drawing log information.

Still another example of the external apparatus is an external computer for performing management (step management or process management) of a step including lithography. For example, the external computer decides a pattern position at which (defect) pattern inspection is performed, based on:

(1) the result of inspecting the wafer confirmed by an electron microscope;
(2) the circuit pattern data (or correction information thereof) included in the drawing log information of the wafer;
(3) the alignment result; and
(4) a location where the environment information changes.

### Second Embodiment

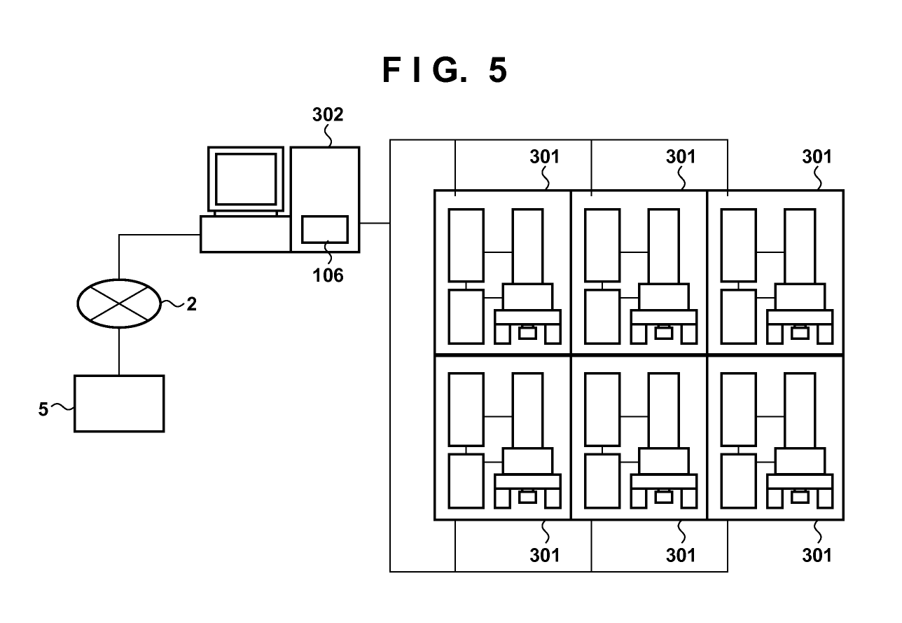

This embodiment relates to a cluster charged particle beam drawing apparatus including a plurality of charged particle optical systems each for irradiating a substrate with a charged particle beam. As shown in FIG. 5, the cluster charged particle beam drawing apparatus according to this embodiment includes a plurality of charged particle beam drawing units 301 and a management apparatus 302. The management apparatus 302 has the function of a transmitter 106 shown in FIG. 1, and is communicably connected, via a LAN 2, to an external apparatus 5 for managing a succeeding step. Each charged particle beam drawing unit 301 corresponds to the charged particle beam drawing apparatus 1 shown in FIG. 1. It is intended to improve the throughput by combining the plurality of charged particle beam drawing units 301. For example, in drawing using charged particle beams, a computer for processing a large amount of circuit pattern data corresponding to a mask is required. However, it is effective to commonly use such a device among the plurality of charged particle beam drawing units in terms of utilization of resources, and it is possible to enjoy the advantage by clustering. Also, for example, if one resist coating/developing apparatus is connected to one charged particle beam drawing unit like an exposure apparatus which uses a mask, the operating time of the resist coating/developing apparatus decreases. In this regard, clustering can increase the availability of the resist coating/developing apparatus.

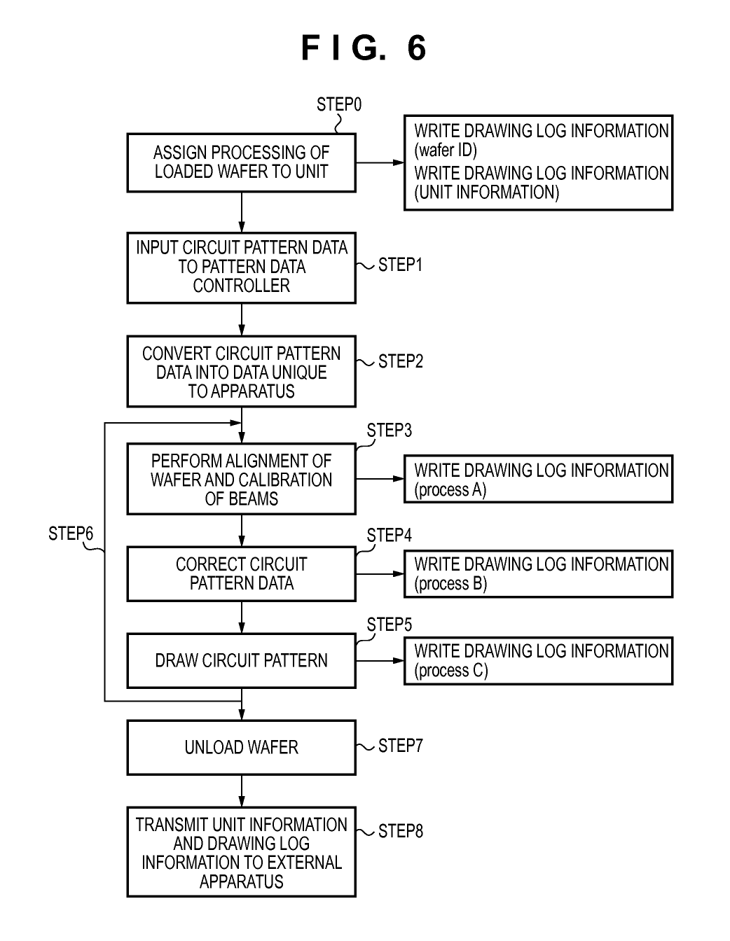

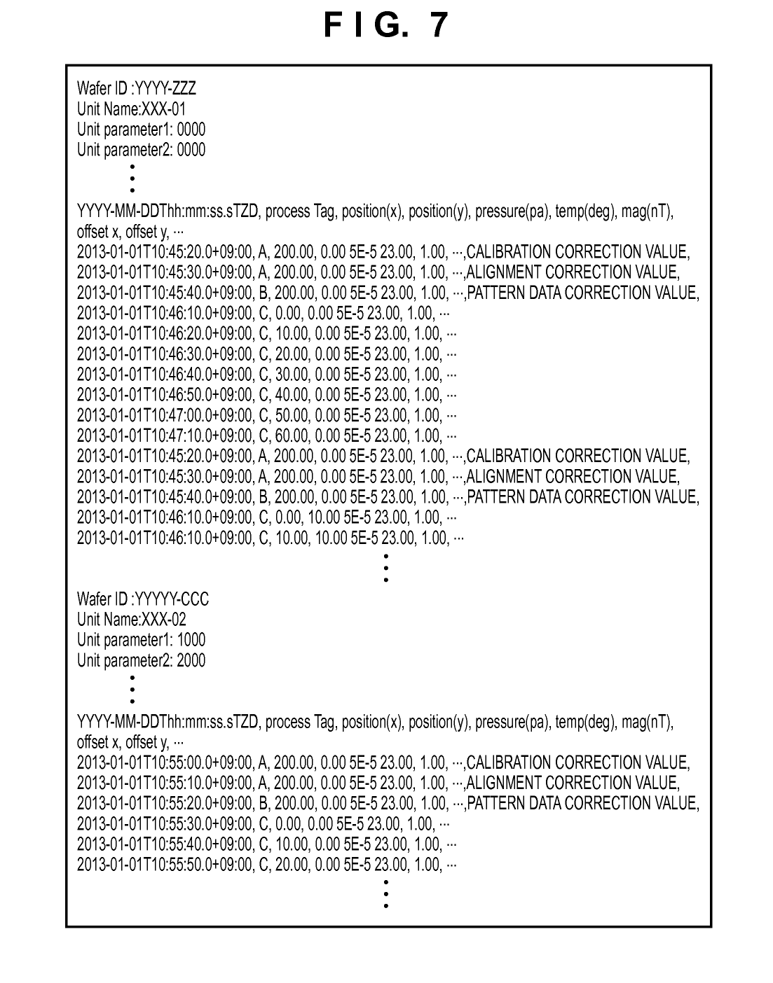

FIG. 6 shows a processing procedure according to this embodiment. First, for a wafer loaded from the resist coating apparatus, the management apparatus 302 assigns processing to one of the units in consideration of the measurement condition in the lithography step and the load status of each unit (step 0). At this time, information for specifying a specific unit which performs drawing on a specific wafer is extracted together with the parameters of a predetermined unit, and written in drawing log information. Each unit performs the processing according to the same procedure as that in the first embodiment (steps 1 to 7), and the drawing log information is transmitted to the external apparatus 5 (step 8). FIG. 7 shows an example when the drawing log information is recorded in a file. As the external apparatus, for example, the following apparatus is assumed.

An example of the external apparatus is the second lithography apparatus for forming an upper layer. The second lithography apparatus corrects, for example, the position of an alignment mark based on circuit pattern data (or correction information thereof), an alignment result, and environment information included in the drawing log information.

Another example of the external apparatus is an external computer for performing management (step management or process management) of a step including lithography. For example, the external computer decides a pattern position at which (defect) pattern inspection is performed, based on:

(1) the result of inspecting the wafer confirmed by an electron microscope;
(2) the circuit pattern data (or correction information thereof) included in the drawing log information of the wafer;
(3) the alignment result; and
(4) a location where the environment information changes.

The external computer for performing step management can select a combination of compatible lithography apparatuses in the mix-and-match process of mixing and using appropriate lithography apparatuses in each step. Based on unit information, this external computer can decide a lithography apparatus to be used in the succeeding step in which patterning is performed next.

According to the above-described embodiment, log information at the time of drawing is transmitted to the external apparatus for managing the succeeding step. In the succeeding step, it is possible to perform processing based on the log information. It is also possible to improve the overlay precision in the succeeding step, and correctly determine a defective item. Furthermore, in the succeeding step, it is possible to correct and adjust processing contents based on the drawing log information. This can improve the manufacturing precision and yield to manufacture semiconductor products as designed, and improve the productivity.

<Embodiment of Method of Manufacturing Article>

A method of manufacturing an article according to an embodiment of the present invention is suitable for manufacturing an article, for example, a microdevice such as a semiconductor device or an element having a microstructure. The method of manufacturing an article according to this embodiment includes a step of forming a latent pattern on a photosensitive agent applied to a substrate (a step of performing drawing on a substrate), and a step of processing (for example, developing) the substrate on which the latent pattern is formed in the above step. This manufacturing method further includes other well-known steps (for example, oxidization, deposition, vapor deposition, doping, planarization, etching, resist removal, dicing, bonding, and packaging). The article manufacturing method according to the embodiment is superior to a conventional method in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-123810, filed Jun. 16, 2014, which is hereby incorporated by reference herein in its entirety.

What is claimed is:

1. A lithography apparatus for performing patterning on a substrate with a charged particle beam, the apparatus comprising:
a controller configured to extract log information to be transmitted to an external apparatus that performs a process on the substrate, on which the patterning has been performed, among log information associated with the patterning; and
a transmitter configured to transmit the extracted log information to the external apparatus.

2. The apparatus according to claim 1, further comprising:
a plurality of patterning devices each configured to perform the patterning,
wherein the controller is configured to extract, as the extracted log information, information for specifying a patterning device that has performed the patterning among the plurality of patterning devices.

3. The apparatus according to claim 1, wherein the controller is configured to extract, as the extracted log information, information of calibration or measurement or both thereof associated with the patterning.

4. The apparatus according to claim 1, wherein the controller is configured to extract, as the extracted log information, information of pattern data used for the patterning, that has been obtained via correction.

5. The apparatus according to claim 1, wherein the controller is configured to extract, as the extracted log information, information of an environment in which the patterning has been performed.

6. The apparatus according to claim 5, wherein the environment is associated with a degree of vacuum, a magnetic field, or a temperature, or any two thereof, or all thereof.

7. The apparatus according to claim 1, wherein the transmitter is configured to transmit the extracted log information to, as the external apparatus, an external apparatus that performs inspection of the substrate on which the patterning has been performed, patterning on the substrate, or process control for the substrate.

8. A method of manufacturing an article, the method comprising steps of:
performing patterning on a substrate using a lithography apparatus; and
processing the substrate, on which the patterning has been performed, to manufacture the article,
wherein the lithography apparatus performs the patterning on the substrate with a charged particle beam, and includes:
a controller configured to extract log information to be transmitted to an external apparatus that performs a process on the substrate, on which the patterning has been performed, among log information associated with the patterning; and
a transmitter configured to transmit the extracted log information to the external apparatus.
